(19) United States
(12) Patent Application Publication
(10) Pub. No.: US 2009/0311840 A1
(43) Pub. Date: Dec. 17, 2009

(54) METHOD OF MANUFACTURING SEMICONDUCTOR DEVICE

(75) Inventor: Takashi ONIZAWA, Kanagawa (JP)

Correspondence Address: YOUNG & THOMPSON, 209 Madison Street, Suite 500, Alexandria, VA, 22314, US

(73) Assignee: NEC ELECTRONICS CORPORATION, KANAGAWA (JP)

(21) Appl. No.: 12/484,460

(22) Filed: Jun. 15, 2009

(30) Foreign Application Priority Data
Jun. 16, 2008 (JP) 2008-156470

(51) Int. Cl. H01L 21/336; H01L 21/26

(52) U.S. Cl. 438/287; 438/301; 438/308; 257/E21.423; 257/E21.433; 257/E21.328

(57) ABSTRACT

A method of manufacturing a semiconductor device includes forming, over a substrate, a gate insulating film containing a high-k insulating film which is composed of a material having a dielectric constant larger than that of silicon dioxide film; forming a gate electrode containing a metal over the gate insulating film; forming extension regions by implanting an dopant into the substrate using the gate electrode as a mask; and annealing the substrate, having the dopant implanted therein, by flash lamp annealing or laser annealing; wherein the annealing further includes: a first step irradiating a substrate with a light pulse having a predetermined peak intensity; and a second step irradiating a substrate with light pulses having peak intensities lower than that of the light pulse used in the first step.

This application is based on Japanese patent application No. 2008-156470 the content of which is incorporated hereinto by reference.

### BACKGROUND

1. Technical Field

The present invention relates to a method of manufacturing a semiconductor device.

2. Related Art

Aiming at preventing the short-channel effect in MOSFET, there has conventionally been adopted formation of shallow SDE(source drain extension) regions in a substrate. As a countermeasure to recent demands on shallowing of the junction of the extension regions, efforts have been made on maximization of the activation of dopants contained therein. More specifically, flash lamp annealing has been adopted in order to maximize the activation of dopants in the extension regions. By flash lamp annealing, the substrate may rapidly be heated, and may rapidly be lowered in the temperature (see Japanese Laid-Open Patent Publication No. 2006-245338, and Japanese Laid-Open Patent Publication No. 2006-279013).

On the other hand, aiming at reducing the thickness of a gate insulating film while suppressing leakage current, there has recently been proposed use of a high-k film as the gate insulating film, and use of a metal gate as a gate electrode.

The conventional semiconductor devices making use of a high-k film as the gate insulating film, and making use of a metal gate, however, raise a problem in that the flash lamp annealing, aimed at achieving higher degrees of activation of the dopant in the extension regions may degrade the mobility of electrons or excessive lowering in the threshold voltage of the semiconductor device, and may thereby degrade performances of the semiconductor devices.

### SUMMARY

According to the present invention, there is provided a method of manufacturing a semiconductor device which includes: forming, over a substrate, a gate insulating film containing a high-k insulating film which is composed of a material having a dielectric constant larger than that of silicon dioxide film; forming a gate electrode containing a metal over the gate insulating film; forming extension regions by implanting an dopant into the substrate using the gate electrode as a mask; and annealing the substrate, having the dopant implanted therein, by flash lamp annealing or laser annealing; wherein the process of annealing further includes: a first step irradiating the substrate with a light pulse having a predetermined peak intensity; and a second step irradiating the substrate with a light pulse having a peak intensity lower than that of the light pulse used in the first step.

According to the present invention, the process of annealing is configured to have a first step irradiating the substrate with a light pulse having a predetermined peak intensity; and a second step irradiating the substrate with a light pulse having a peak intensity lower than that of the light pulse used in the first step.

In this way, the dopant may be activated to a higher degree, while preventing the electron mobility or the threshold voltage from being lowered, and thereby the semiconductor device may be suppressed from being degraded in performances.

According to the present invention, a method of manufacturing a semiconductor device capable of fully activating dopants and of preventing the semiconductor device from being degraded in performances, may be provided.

### BRIEF DESCRIPTION OF THE DRAWING

The above and other objects, advantages and features of the present invention will be more apparent from the following description of certain preferred embodiments taken in conjunction with the accompanying drawings, in which:

FIGS. 1A to 1D are drawings illustrating steps of manufacturing a semiconductor device according to one embodiment of the present invention;

FIG. 2 is a drawing illustrating a relation between duration of irradiation of light pulses and intensity, adopted to the embodiment;

FIG. 3 is a drawing illustrating another relation between duration of irradiation of light pulses and intensity, adopted to the embodiment;

FIGS. 4A and 4B are drawings illustrating relations between junction depth (Xj) and sheet resistance (Rs) in Examples and Comparative Examples;

FIG. 5 is a drawing illustrating electron mobility in the nMOS-FETs in Example 1 and Comparative Examples 1, 3; and

FIG. 6 is a drawing illustrating shift of threshold voltage in the nMOS-FETs in Example 1 and Comparative Examples 1, 3.

### DETAILED DESCRIPTION

The invention will now be described herein with reference to an illustrative embodiments. Those skilled in the art will recognize that many alternative embodiments can be accomplished using the teachings of the present invention and that the invention is not limited to the embodiment illustrated for explanatory purposes.

Embodiments of the present invention will be explained below, referring to the attached drawings.

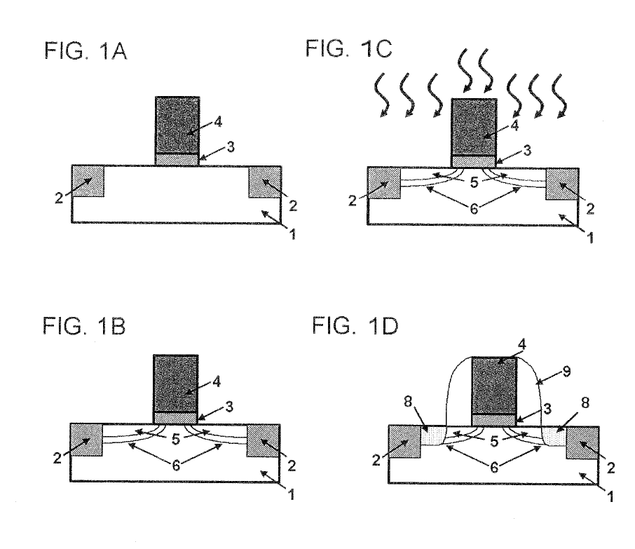

First, an outline of a method of manufacturing a semiconductor device according to this embodiment will be explained, referring to FIGS. 1A to 1D.

The method of manufacturing a semiconductor device of this embodiment includes forming, over a substrate 1, a gate insulating film 3 containing a high-k insulating film which is composed of a material having a dielectric constant larger than that of silicon dioxide film; forming a gate electrode 4 containing a metal over the gate insulating film 3; forming extension regions 5 by implanting an dopant into the substrate 1 using the gate electrode 4 as a mask; and annealing the substrate 1, having the dopant implanted therein, by flash lamp annealing or laser annealing.

The process of annealing further includes: a first step irradiating the substrate 1 with a light pulse having a predetermined peak intensity; and a second step irradiating the substrate with a light pulse having a peak intensity lower than that of the light pulse used in the first step.

The flash lamp annealing herein means annealing by irradiating light having a continuous wavelength spectrum. On the other hand, the laser annealing herein means annealing by irradiating light having a single wavelength.

Next, the method of manufacturing a semiconductor device of this embodiment will be detailed.

As illustrated in FIG. 1A, the substrate 1 is prepared. The substrate 1 is a semiconductor substrate, and is herein a silicon substrate. The substrate 1 has device isolation regions 2, such as STI (Shallow Trench Isolation), formed therein. Over the substrate 1, the gate insulating film 3 is formed, and the gate electrode 4 is formed over the gate insulating film 3.

For more details, over the surface of the substrate 1, a film to be processed to give the gate insulating film 3 and a film to be processed to give the gate electrode 4 are formed, and these films are then etched to form the gate insulating film 3 and the gate electrode 4.

The gate insulating film 3 herein is preferably a high-k insulating film configured to contain at least one species selected from the group consisting of Hf, Zr, Al, Y, La and Mg. For example, the gate insulating film 3 may be exemplified by those containing at least one high-k film material selected from the group consisting of HfO₂, ZrO₂, HfSiO, ZrSiO, HfAlO, ZrAlO, Y₂O₃, La₂O₃, MgO and nitrides of any of these species. More specifically, in this embodiment, the gate insulating film is a HfSiON film.

The gate electrode 4 preferably contains one or more metals selected from the group consisting of Ti, Zr, Hf, V, Nb, Ta, Mo and W, and may be exemplified by TiN, ZrN, HfN, VN, NbN, TaN, MoN, WN, TiSiN, HfSiN, VSiN, NbSiN, TaSiN, MoSiN, WSN, WAlN, TiAlN, HfAlN, VAlN, NbAlN, TaAlN and MoAlN. More specifically, in this embodiment, the gate electrode 4 is made of TaSiN.

Thereafter, as illustrated in FIG. 1B, boron fluoride (BF₂) is introduced by pocket ion implantation, while using the gate electrode 4 as a mask, to thereby form p-type halo regions 6 in the surficial region of the silicon substrate 1.

The halo regions 6 herein are regions provided below the gate electrode 4, and at the end portions of source/drain regions 8 formed later (see FIG. 1D). The halo regions 6 function as a stopper against punch-through of electrons.

The halo regions 6 may be formed by introducing the dopant using the gate electrode 4 as a mask, in the direction inclined typically at 30° away from the normal direction of the substrate 1, while rotating the whole substrate 1.

Thereafter, an arsenic (As) ion is introduced into the substrate 1 by ion implantation, to thereby form the n-type extension regions 5.

Typical conditions of implantation into the individual regions may be 45 keV, 2×10¹⁴ cm⁻² and a 30° inclination for BF₂; and 2 keV, 1×10¹⁵ cm⁻² and vertical for As.

The dopant for forming the p-type halo regions 6, exemplified by boron fluoride in the above, is not limited thereto, and may be boron, In or the like.

Next, as illustrated in FIG. 1C, the dopant is activated and any defects induced by ion implantation are restored, by flash lamp annealing or laser annealing, over a duration of annealing of 5 msec or longer and 100 msec or shorter.

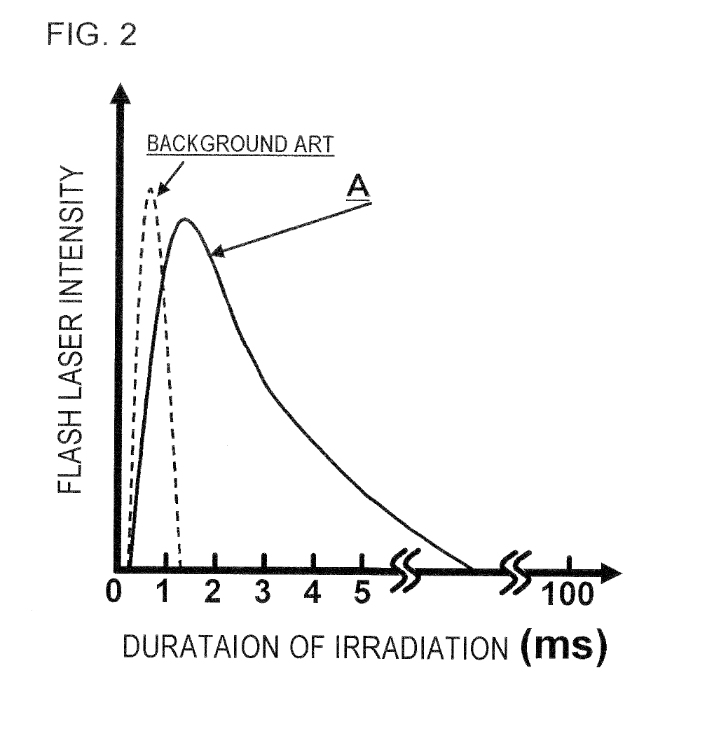

A profile of the light pulses in the flash lamp annealing or laser annealing may be designed as illustrated in FIG. 2. The ordinate of FIG. 2 represents the intensity of light pulses, and the abscissa represents the duration of irradiation (duration of annealing).

More specifically, the intensity of lamp light or laser light is raised to a certain intensity, and after the certain intensity is achieved, the intensity is then lowered. Typical surface temperature of the substrate may be over 1300 degree C. from a process simulation.

For example, as expressed by profile “A”, the rate of fall of the intensity of lamp light or laser light down from the certain intensity may be set slower than the rate of elevation in the intensity of lamp light or laser light up to the certain intensity. For example, a light pulse having a predetermined peak intensity may be irradiated (first step), and then a light pulse having a peak intensity lower than that of the previous light pulse may be irradiated plural times (second step), so as to trace the profile “A”. The total duration of irradiation of light pulses in the second step will be longer than the total duration of irradiation of light pulse in the first step. The profile “A” may be traceable by successively irradiating a plurality of light pulses (multi-pulse) in the second step, while controlling the peak intensities thereof so as to be gradually lowered. It is preferable in this case that the pulse width of the individual pulse is nearly equal.

In this case, in the process of annealing, the rate of elevation of temperature of the substrate surface will be faster than the rate of fall of temperature of the surface of the substrate 1. Note that, the flash lamp annealing can anneal the entire surface of a wafer by a single shot, whereas the laser annealing can anneal only a limited region.

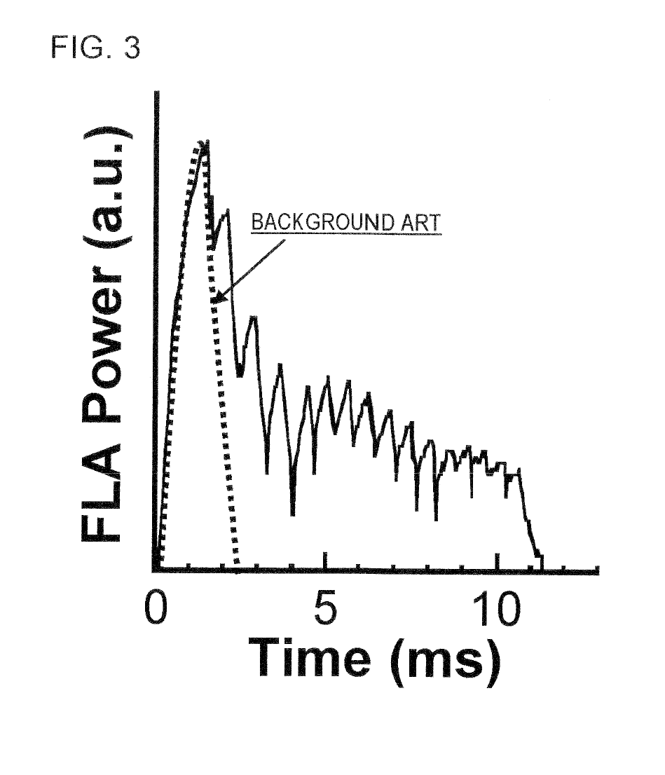

Alternatively, the flash lamp annealing or the laser annealing may be conducted according to a multi-pulse mode illustrated in FIG. 3 (solid line in FIG. 3). In this case, the process of annealing includes a first step irradiating the substrate with a light pulse having a predetermined peak intensity; and a second step irradiating the substrate with light pulses having peak intensities lower than that of the light pulse used in the first step. The total duration of irradiation of light pulses in the second step is longer than the total duration of irradiation of light pulse in the first step.

For example, a high-power light pulse having a half-value width of 1.4 msec is used in the first step, then low-power light pulse is successively used plural times over a duration of approximately 10 msec (multi-pulse). In this case, it is preferable that the pulse width of each pulse is nearly equal. The total duration of irradiation in the flash lamp annealing or laser annealing is preferably adjusted to 5 msec or longer and 100 msec or shorter.

Also in this case, the rate of fall of the intensity of lamp light or laser light down from a certain intensity is slower than the rate of elevation in the intensity of lamp light or laser light up to the certain intensity.

In this embodiment, in the process of annealing, the substrate is irradiated with a plurality light pulses of the multi-pulse mode which are successively irradiated onto the substrate, wherein the substrate is irradiated with the light pulse having a maximum peak intensity, and then light pulses having an intensity lower than the maximum intensity are irradiated. Assuming now the duration of time ranging from the start of irradiation of light pulses up to the point of time when the irradiation of the light pulses comes to the end is plotted on the abscissa, and that the intensity of light pulse is plotted on the ordinate, a position of a maximum peak intensity of the light pulse along the time axis resides more closer to the start of irradiation of light pulses, rather than the end of irradiation of light pulses. In other words, the duration of time ranging from the start of irradiation of a series of the plurality of light pulses upto the point of time when the maximum peak intensity of the light pulse is achieved, is shorter than the duration of time ranging from the point of time where the maximum peak intensity of the light pulse is achieved up to the end of irradiation of the light pulses.

Here, peak intensities of the light pulses in the second step are smaller than the maximum peak intensity in the first step.

In this process of annealing, the flash lamp annealing or the laser annealing is, but annealing for sintering is not carried out after the flash lamp annealing or the laser annealing.

Thereafter, as illustrated in FIG. 1D, sidewalls 9 are formed on the side faces of the gate electrode 4. A dopant is then implanted to form the source/drain regions 8. Arsenic (As), for example, is used as the dopant. The source/drain regions 8 may be either of those having an dopant concentration higher or lower than the dopant concentration of the extension regions 5.

Thereafter, the annealing is optionally carried out by flash lamp annealing or laser annealing, to thereby fully activate the dopant in the source/drain regions 8.

By these processes, a semiconductor device of an nMOS type may be obtained.

Next, operations of this embodiment will be explained. In this embodiment, the process of annealing is configured to include a first step irradiating the substrate with a light pulse having a predetermined peak intensity to the substrate 1; and a second step irradiating light pulses having peak intensities lower than that of the light pulse used in the first step.

By virtue of this configuration, the dopant in the extension regions 5 may fully be activated, while preventing the electron mobility or the threshold voltage from being lowered, and thereby the semiconductor device may be suppressed from being degraded in performances.

The conventional flash lamp annealing and so forth have been known to degrade the electron mobility and to lower the threshold voltage, and there has been known also a tendency of improvement in the degradation it the electron mobility and the lowering in threshold voltage, if the flash lamp annealing was followed by annealing for sintering in a hydrogen atmosphere at a relatively lower temperature, before the source/drain regions are formed. However, the annealing for sintering inevitably caused diffusion of the dopant contained in the extension regions.

In contrast, this embodiment successfully solves the conventional tough problem of trade-off between thorough activation of dopant in the extension regions 5 and degradation of the electron mobility and lowering in the threshold voltage, by conducting the flash lamp annealing or laser annealing, which includes the first step of irradiating the substrate with a light pulse having a predetermined peak intensity to the substrate 1, and a second step irradiating light pulses having peak intensities lower than that of the light pulse used in the first step.

In addition, this embodiment adjusts the total duration of irradiation by flash lamp annealing or laser annealing to 5 msec or longer and 100 msec or shorter. By virtue of the adjustment, the dopant in the extension region 5 may more exactly be activated, and thereby degradation in the electron mobility and lowering in the threshold voltage may exactly be avoidable.

In the process of annealing, by setting the rate of elevation of temperature of the surface of the substrate 1 faster than the rate of fall of temperature of the surface of the substrate 1, any crystal defect induced by ion implantation for forming the source/drain regions may more effectively be restored.

In addition, by configuring the process of annealing by the first step of irradiating the substrate 1 with a light pulse having a predetermined peak intensity, and a second step irradiating the substrate with light pulses having peak intensities lower than that of the light pulse used in the first step, over a longer duration of irradiation of light pulse than in the first step, the dopant may be activated in the first step, and warping of wafer, crystal defects and so forth induced in the first step may be restored in the second step. Moreover, by conducting the second step by flash lamp annealing or laser annealing, diffusion or inactivation of the dopant may be avoidable.

Note that the present invention is not limited to the above-described embodiments, and allows any modification and improvement within the scope in which the object of the present invention is attainable.

For example, the foregoing embodiments have discussed the flash lamp annealing or the laser annealing based on the multi-pulse mode in which the individual pulse had an almost same pulse width as illustrated in FIG. 3. The present invention is, however, not limited to the embodiments, but are not limiter thereto, and typically allows irradiation of light pulses having a smaller pulse width and a larger peak intensity in the first step, and irradiation of light pulses having larger pulse widths and smaller peak intensities in the second step.

### EXAMPLES

Examples of the present invention will be explained in the next.

### Example 1

An nMOS transistor was manufactured in this embodiment.

The semiconductor device was manufactured similarly to as described in the foregoing embodiments.

Gate insulating film: HfSiON film

Gate electrode: TaSiN

were adopted. Boron fluoride (BF₂) was introduced by pocket ion implantation into the surficial region of the silicon substrate 1, while using the gate electrode as a mask to thereby form the p-type halo regions, and arsenic (As) ions were then implanted to form the extension regions. Typical conditions of the individual implantations may be 45 keV, 2×10¹⁴ cm⁻² and a 30° inclination for BF₂; and 2 keV, 1×10¹⁵ cm⁻² and vertical for As.

In the process of a first step annealing, the light pulses based on the flash lamp annealing according to the profile illustrated in FIG. 3 were used. A High-power light pulse having a half-value width of 1.4 msec was used, and a plurality of low-power light pulses was then used over approximately 10 msec (flash lamp annealing over 11 msec, based on the multi-pulse mode).

Thereafter, As ions were implanted into the substrate, to thereby form the source/drain regions.

### Example 2

A pMOS transistor was manufactured in this embodiment. An n-well was formed in the device forming region of the silicon substrate, and the gate insulating film and the gate electrode same as those in Example 1 were formed. The n-type halo regions were formed, and the p-type extension regions were then formed. More specifically, Ge was implanted at 10 keV and 5×10¹⁴ cm⁻², and B was then implanted at 0.5 keV and 1×10¹⁵ cm⁻². The flash lamp annealing was conducted under conditions same as those in Example 1, and a p-type dopant was implanted to form the source/drain regions.

### Comparative Example 1

In the process of annealing, flash lamp annealing was conducted over a duration of 0.8 msec. The flash lamp annealing herein was conducted using a single light pulse. Any other aspects are same as those in Example 1.

### Comparative Example 2

In the process of annealing, flash lamp annealing was conducted over a duration of 0.8 msec. The flash lamp annealing herein was conducted using a single light pulse. Any other aspects are same as those in Example 2.

### Comparative Example 3

In the process of annealing, flash lamp annealing was conducted over a duration of 0.8 msec, followed by spike annealing at 850 to 1050° C. (three steps at 850° C., 950° C. and 1050° C.). The flash lamp annealing herein was conducted using a single light pulse. Any other aspects are same as those in Example 1.

### Comparative Example 4

In the process of annealing, flash lamp annealing was conducted over a duration of 0.8 msec, followed by spike annealing at 850 to 1050° C. (three steps at 850° C., 950° C. and 1050° C.). The flash lamp annealing herein was conducted using a single light pulse. Any other aspects are same as those in Example 2.

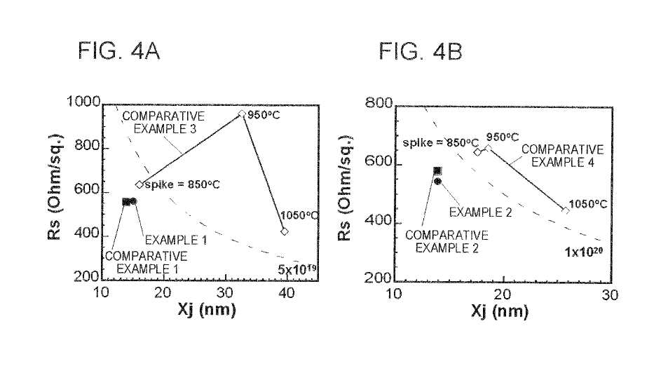

Results are shown in FIGS. 4A and 4B. The drawings illustrate relations between junction depth (Xj) and sheet resistance (Rs). It is known that Comparative Examples 3, 4 in which the flash lamp annealing was followed by spike annealing caused upper-right shifts in the Rs-Xj relation (degradation) due to inactivation and diffusion of the dopant, as compared with Examples 1, 2, and Comparative Examples 1, 2 in which only flash lamp annealing was conducted.

On the other hand, Examples 1, 2 are found to successfully achieve non-diffusive, high-activation annealing, as judged from the Rs-Xj relation equivalent to those in Comparative Examples 1, 2.

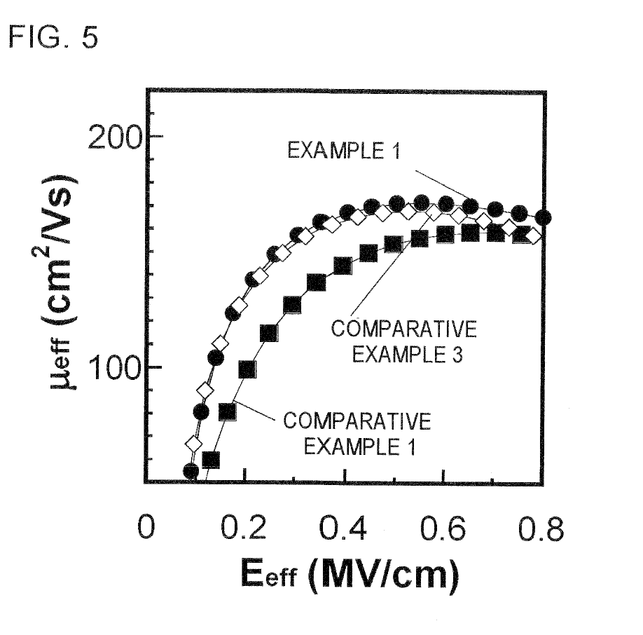

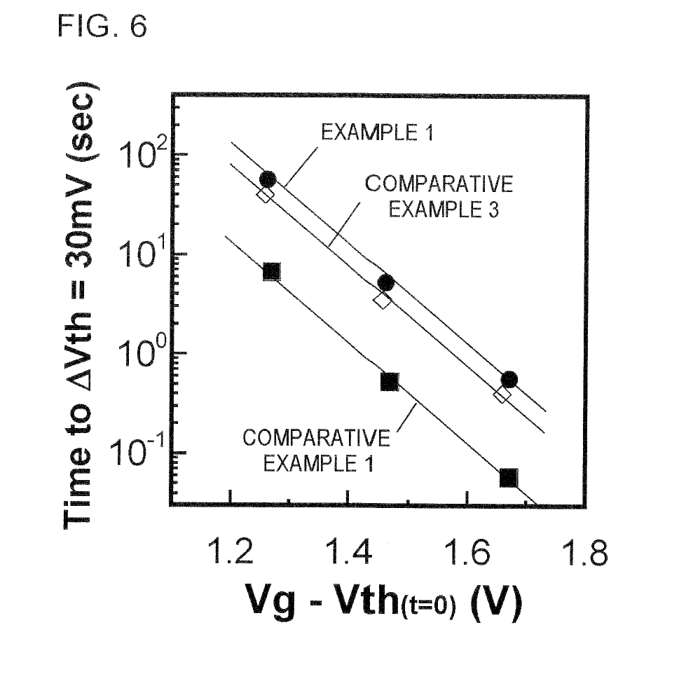

FIG. 5 illustrates electron mobility in the nMOS-FETs in Example 1, and Comparative Examples 1, 3. FIG. 6 illustrates shifts of threshold voltage in the nMOS-FETs in Example 1 and Comparative Examples 1, 3, relative to temperature and voltage stresses. The electron mobility and the shift of threshold voltage in Example 1 were found to be equivalent or superior to those in Comparative Example 3. It has generally been believed that the electron mobility and the shift of threshold voltage may be improved by annealing after the flash lamp annealing.

It is clarified from the results that the present invention is effective in further activating the dopant, and in improving the transistor characteristics.

It is apparent that the present invention is not limited to the above embodiment, that may be modified and changed without departing from the scope and spirit of the invention.

What is claimed is:

1. A method of manufacturing a semiconductor device comprising:
forming, over a substrate, a gate insulating film containing a high-k insulating film which is composed of a material having a dielectric constant larger than that of silicon dioxide film;
forming a gate electrode containing a metal over said gate Insulating film;
forming source-drain extension regions by implanting an dopant into said substrate using the gate electrode as a mask; and
annealing said substrate, having said dopant implanted therein, by flash lamp annealing or laser annealing;
wherein said annealing further comprises:
a first step irradiating the substrate with a light pulse having a predetermined peak intensity; and
a second step irradiating the substrate with a light pulse having a peak intensity lower than that of the light pulse used in said first step.

2. The method of manufacturing a semiconductor device as claimed in claim 1,
wherein in said annealing, the total duration of irradiation in said second step is longer than the total duration of irradiation in said first step.

3. The method of manufacturing a semiconductor device as claimed in claim 2,
wherein in said annealing, the flash lamp annealing or the laser annealing is conducted based on a multi-pulse mode by irradiating a plurality of light pulses.

4. The method of manufacturing a semiconductor device as claimed in claim 1,
wherein in said annealing, said substrate is irradiated with a plurality of light pulses to proceed the annealing,
said plurality of light pulses are according to a sequence such as irradiating the substrate with a light pulse having a maximum peak intensity in said first step, and then irradiating light pulses having peak intensities lower than said maximum peak intensity in said second step; and
the duration of time ranging from the start of irradiation of said plurality of light, pulses up to the point of time when the maximum peak intensity of light pulse is achieved, is shorter than the duration of time ranging from the point of time when the maximum peak intensity of light pulse is achieved up to the end of irradiation of said plurality of light pulses.

5. The method of manufacturing a semiconductor device as claimed in claim 1,
wherein in said annealing, said substrate is heated up to a predetermined temperature, and then cooled,
the rate of elevation of temperature of said substrate being faster than the rate of fall in temperature of said substrate.

6. The method of manufacturing a semiconductor device as claimed in claim 1,
wherein in said annealing, the total duration of irradiation by flash lamp annealing or laser annealing is adjusted to 5 msec or longer and 100 msec or shorter.

7. The method of manufacturing a semiconductor device as claimed in claim 1,
wherein said gate electrode is configured to contain at least one metal selected from the group consisting of Ti, Zr, Hf, V, Nb, Ta, Mo and W.

8. The method of manufacturing a semiconductor device as claimed in claim 1,
wherein said high-k insulating film is configured to contain at least one species selected from Hf, Zr, Al, Y, La and Mg.
